(19) United States
(12) Patent Application Publication
(10) Pub. No.: US 2002/0109201 A1
(43) Pub. Date: Aug. 15, 2002

(54) Rectifying device and method of fabrication thereof

(76) Inventor: Chein-Chang Chen, Taipei Hsien (TW)

Correspondence Address: BACON & THOMAS, PLLC, 4th Floor, 625 Slaters Lane, Alexandria, VA, 22314-1176, US

(21) Appl. No.: 09/779,515

(22) Filed: Feb. 9, 2001

(51) Int. Cl. H01L 27/095; H01L 29/47; H01L 29/812; H01L 31/07; H01L 31/108

(52) U.S. Cl. 257/485

(57) ABSTRACT

A rectifying device and method of fabrication thereof is disclosed. The method comprises the steps of plating a metal (e.g., aluminum) layer on top and bottom surfaces of silicon wafer in a vacuum, cutting silicon wafer into a plurality of identical silicon dies, coupling a molybdenum layer on either top or bottom surface of silicon die by brazing metal film therebetween, performing an etching on silicon die after silicon die and molybdenum layers are formed together, filling a uniform glass paste onto the peripheral surface of silicon die between the molybdenum layers, and sintering the glass paste to form a glass layer on the peripheral surface of silicon die. This ensures that the rectifying device can operate normally when mounted on a high power high input current circuit. Also, a conductive metal (e.g., nickel or gold) layer is coated on the portion of either molybdenum layer which is not in contact with silicon die. Further, a conductive lead coupled to a circuit is welded to either conductive metal layer.

### FIELD OF THE INVENTION

The present invention relates to rectifying devices and more particularly to a rectifying device and method of fabrication thereof with improved characteristics.

### BACKGROUND OF THE INVENTION

A conventional rectifying device 10 is shown in FIG. 1 comprising a silicon die 17, two copper members 13 each coupled to an end of silicon die 17 by welding a first pad 14 therebetween, and two conductive leads 11 each having one end coupled to an end of copper member 13 by welding a second pad 12 therebetween and the other end coupled to a predetermined circuit. After copper members 13 and silicon die 17 are formed together, an etching is performed on silicon die 17. Thereafter, an insulated plastics 15 is coated on the silicon die 17 and copper silicon dies 13. This completes a rectifying device 10.

Another conventional rectifying device 20 is shown in FIG. 2 comprising a silicon die 27, two copper members 23 each coupled to an end of silicon die 27 by welding a first pad 24 therebetween, a conductive lead 21 having one end coupled to the top end of copper member 23 by welding a second pad 22 therebetween and the other end coupled to a predetermined circuit, and a seat 29 having a recess 291 coupled to the bottom end of the lower copper member 23 by welding a second pad 22 therebetween. After copper members 23 and silicon die 27 are formed together, an etching is performed on silicon die 27. Thereafter, resin 25 is filled in recess 25 to coat on the silicon die 27 and copper silicon dies 23. This completes a rectifying device 20. Rectifying device 20 is fastened to a cooling seat or cooling fins (not shown) by threadedly securing the threaded portion 292 of seat 29 thereto. When rectifying device 20 is served as rectifying means for a high power high input current circuit, this may transfer heat generated in the rectifying device 20 to the cooling seat (or cooling fins) through the seat 29.

It is understood from above that such conventional rectifying devices are made by performing the steps of coupling silicon die and copper members together by welding pad therebetween, and coupling copper members and conductive lead together by welding pad therebetween. It is known that the melting temperature of a typical pad is about 300° C. As such, such rectifying device is susceptible to damage when used as rectifying means for a high power high input current circuit, a circuit in the engine room of an automobile, a circuit in a boiler room, or in any high temperature operating environment. It is also known that in the fabricating process of above rectifying device, only resin or insulated plastics is coated on silicon die after the silicon die is etched. However, the melting temperature of resin or insulated plastics is relatively low. As such, such rectifying device is susceptible to damage when used as rectifying means for a high power high input current circuit or in any high temperature operating environment. This may cause malfunction of an electronic equipment incorporated with such rectifying device, thus shortening the useful life and lowering the quality thereof. Further, a frequent maintenance of the electronic equipment is inevitable. Thus, it is desirable to provide an improved rectifying device in order to overcome the above drawbacks of prior art.

### SUMMARY OF THE INVENTION

It is an object of the present invention to provide a rectifying device and method of fabrication thereof wherein a molybdenum layer is coupled to either surface of silicon die by brazing a metal film therebetween such that the silicon die and the molybdenum layers are formed together. Then, a sintering is performed on the glass paste to form a glass layer on the peripheral surface of silicon die. This ensures that the rectifying device can operate normally when mounted on a high power high input current circuit.

In one aspect of the present invention, a conductive metal layer is coated on the portion of either molybdenum layer which is not in contact with silicon die after glass layer is formed on the peripheral surface of silicon die. Conductive metal layer has a better conductivity such that the rectifying device may be mounted on a predetermined circuit by employing a surface mounting technology.

In another aspect of the present invention, a molybdenum layer is coupled to either surface of silicon die by brazing a metal film therebetween such that the silicon die and the molybdenum layers are formed together. This ensures that the junctions of the silicon die with either molybdenum layer can withstand a high operating temperature for an extended period of time.

In still another aspect of the present invention, fill a uniform glass paste onto the peripheral surface of silicon die and sinter the glass paste to form a glass layer on the peripheral surface of silicon die. This ensures that the rectifying device can either operate normally when mounted on a high power high input current circuit or withstand a high operating temperature for an extended period of time.

The above and other objects, features and advantages of the present invention will become apparent from the following detailed description taken with the accompanying drawings.

### BRIEF DESCRIPTION OF THE DRAWINGS

FIG. 1 is a cross-sectional view of a conventional rectifying device;

FIG. 2 is a cross-sectional view of another conventional rectifying device;

FIG. 3 is a cross-sectional view of a first preferred embodiment of rectifying device according to the invention;

FIG. 4 is a cross-sectional view of a filling device for fabricating a rectifying device according to the invention;

FIG. 5 is a cross-sectional view of a second preferred embodiment of rectifying device according to the invention; and

FIG. 6 is a cross-sectional view of a third preferred embodiment of rectifying device according to the invention.

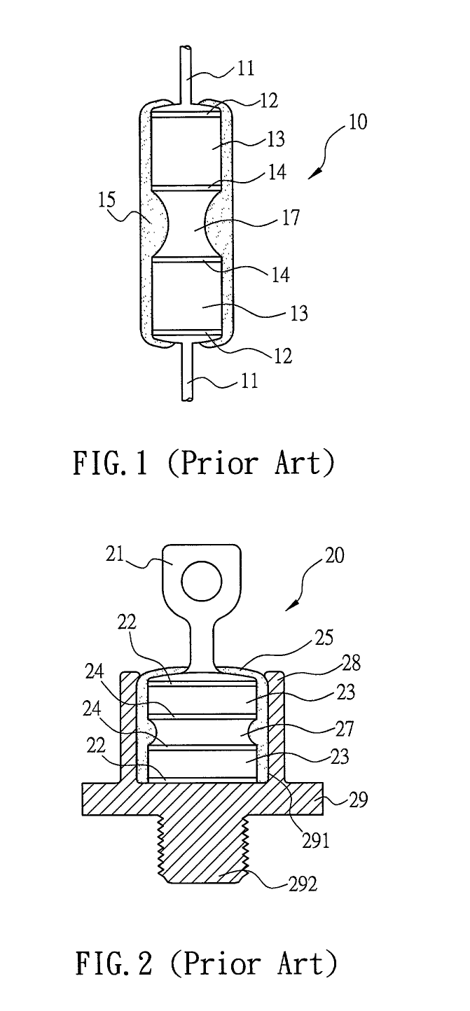

### DETAILED DESCRIPTION OF THE PREFERRED EMBODIMENTS

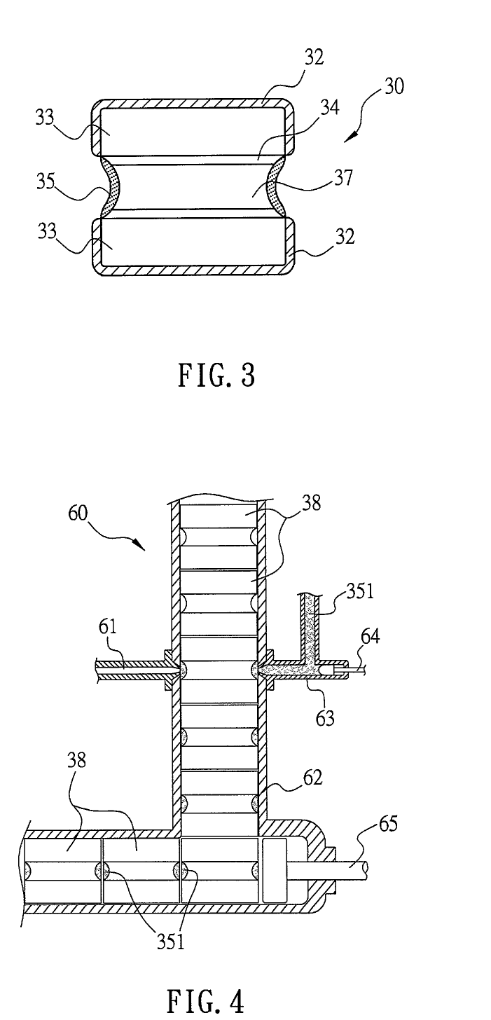

Referring to FIGS. 3, 5, and 6, there is shown a rectifying device constructed in accordance with the invention. The method of fabricating a rectifying device comprises (1) plating a metal (e.g., aluminum) layer 34 on top and bottom surfaces of silicon wafer in a vacuum environment; (2) cutting silicon wafer into a plurality of identical silicon dies 37 each having a predetermined size; (3) coupling a molybdenum layer 33 on either top or bottom surface of silicon die 37 by brazing the metal film 34 therebetween; (4) performing an etching on silicon die 37 after silicon die 37 and the molybdenum layers 33 are formed together; (5) filling a uniform glass paste made from glass powder and adhesive onto the peripheral surface of silicon die 37 between the molybdenum layers 33; and (6) sintering the glass paste to form a glass layer 35 on the peripheral surface of silicon die 37. This completes a rectifying device 30.

Referring to FIG. 3, there is shown a first preferred embodiment of rectifying device 30 according to the invention. A conductive metal (e.g., nickel or gold) layer 32 is coated on the portion of either molybdenum layer 33 which is not in contact with silicon die 37 after glass layer 35 is formed on the peripheral surface of silicon die 37. Conductive metal layer 32 is integrally formed with molybdenum layer 33 and has a better conductivity. As such, rectifying device 30 may be mounted on a predetermined circuit by employing a surface mounting technology.

The process of fabricating a rectifying device 30 of the invention may be detailed by the steps of: (a) silicon die forming wherein first place a finished silicon wafer in a vacuum chamber, sputter or plate an aluminum layer 34 on top and bottom surfaces of silicon wafer, and cut silicon wafer into a plurality of identical silicon dies 37 each having a predetermined size; (b) brazing wherein couple a molybdenum layer 33 on either top or bottom surface of silicon die 37 by brazing the aluminum layer 34 therebetween in a temperature about 720° C. such that silicon die 37 and the molybdenum layers 33 are formed together; (c) etching wherein perform an etching on silicon die 37, perform a cleaning on the etched silicon die 37, and perform a curing on silicon die 37; (d) glass sintering wherein fill a uniform glass paste made from glass powder and adhesive onto the peripheral surface of silicon die 37 between the molybdenum layers 33, and sinter the glass paste to form a glass layer 35 on the peripheral surface of silicon die 37. Referring to FIG. 4, there is shown a filling device 60 for fabricating a rectifying device according to the invention. In operation, filling device 60 first fill a uniform glass paste onto the peripheral surface of silicon die 37 between the molybdenum layers 33. The coupled silicon die 37 and molybdenum layer 33 (i.e., unfinished product 38) is then transferred to a passage 62 by a conveyor (not shown). A vacuum device 61 provided on a side of passage 62 is activated to pump all air out of the peripheral surface of silicon die 37 when the unfinished product 38 is brought to a predetermined filling position. At the same time, a plunger device 64 provided on the other side of passage 62 is activated to squeeze glass paste 351 in the pipe 63 into the peripheral surface of silicon die 37. A ram 65 provided at the bottom of passage 62 is activated to sequentially extrude the unfinished product 38 out of passage 62 for performing a sintering on the unfinished product 38 thereafter; and finally (e) conductive metal layer plating wherein a conductive metal layer 32 is coated on the portion of either molybdenum layer 33 which is not in contact with silicon die 37. This completes the rectifying device 30.

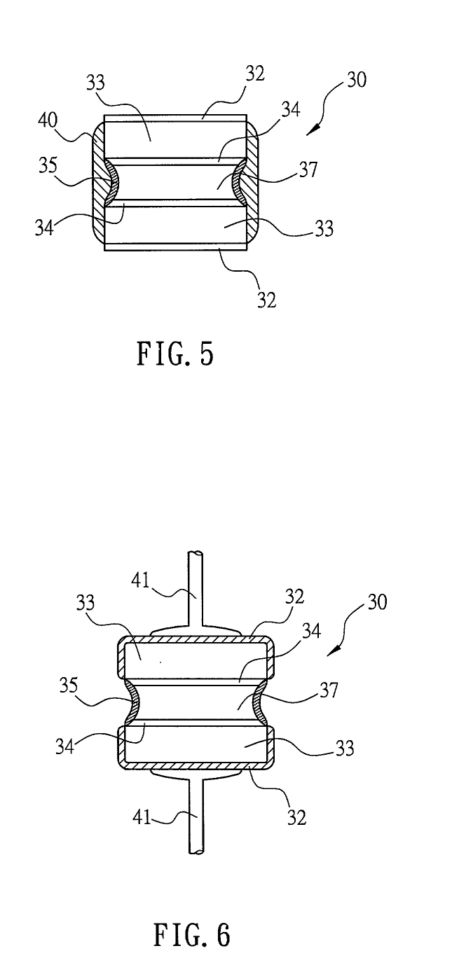

Referring to FIG. 5, there is shown a preferred embodiment of rectifying device 30 according to the invention. In the embodiment, the unfinished product of rectifying device is placed in a mold prior to encapsulation. In the encapsulation process, resin 40 is coated onto the peripheral surface of silicon die 37 and molybdenum layers 33. Finally, a conductive metal layer 32 is coated on the top of one molybdenum layer 33 and the bottom of the other molybdenum layer 33 which are not in contact with silicon die 37 respectively. This completes the rectifying device 30. Hence, rectifying device 30 may be mounted on a predetermined circuit by coupling the conductive metal layers 32 to the predetermined circuit by employing a surface mounting technology.

Referring to FIG. 6, there is shown a preferred embodiment of rectifying device 30 according to the invention. In the embodiment, a conductive lead 41 is welded to either conductive metal layer 32. Further, conductive leads 41 are coupled to a predetermined circuit. Alternatively, one conductive metal layer 32 is welded to a recess of a cooling seat (not shown).

In brief, rectifying device 30 of the invention may be mounted on a predetermined circuit by coupling the conductive metal layers 32 to the predetermined circuit by employing a surface mounting technology, thus eliminating conventional conductive lead which occupies a considerable amount of space. Hence, the invention has the benefits of saving space, compactness, reduced space in storage and transportation, space reduction in the mounted printed circuit board (PCB), no deformation possible on conductive lead in delivery and installation, precise positioning for automatic mounting machine in assembly, and efficiency and quality improvement on assembling components on PCB. Moreover, in fabricating rectifying device 30 of the invention, a molybdenum layer 33 is coupled to either top or bottom surface of silicon die 37 by brazing aluminum layer 34 therebetween in a high temperature condition such that silicon die 37 and the molybdenum layers 33 are formed together. Also, a sintering is performed on the glass paste to form a glass layer on the peripheral surface of silicon die 37. This ensures that rectifying device 30 can withstand a high operating temperature for an extended period of time when rectifying device 30 is mounted on a high power high input current circuit.

While the invention has been described by means of specific embodiments, numerous modifications and variations could be made thereto by those skilled in the art without departing from the scope and spirit of the invention set forth in the claims.

What is claimed is:

1. A rectifying device comprising:
a silicon die with a metal film plated on either surface thereof;
a pair of molybdenum layers each sized to be substantially the same as the silicon die, each molybdenum layer being coupled to the surface of the silicon die with the metal film plated thereon by brazing each metal film between the silicon die and each molybdenum layer for forming the silicon die and the molybdenum layers together; and
a glass layer formed by sintering a glass paste onto the peripheral surface of the silicon die.

2. The rectifying device of claim 1, further comprising a first conductive metal layer coated on the portion of either molybdenum layer which is not in contact with the silicon die.

3. The rectifying device of claim 1, further comprising a resin coated onto the peripheral surface of the silicon die and the molybdenum layers and a second conductive metal layer coated on one surface of one molybdenum layer and the other surface of the other molybdenum layer which are not in contact with the silicon die respectively.

4. The rectifying device of claim 2 or 3, further comprising two conductive leads each welded to one of the first and the second conductive metal layers.

5. A method of fabricating a rectifying device comprising the steps of:
(1) plating a metal film on either surface of a silicon wafer in a vacuum;
(2) cutting the silicon wafer into a plurality of identical silicon dies each having a predetermined size;
(3) coupling a molybdenum layer on either surface of the silicon die by brazing the metal film therebetween;
(4) performing an etching on the silicon die after the silicon die and the molybdenum layers are formed together;
(5) filling a uniform glass paste made from glass powder and adhesive onto the peripheral surface of the silicon die between the molybdenum layers; and
(6) sintering the glass paste to form a glass layer on the peripheral surface of the silicon die.

6. The method of claim 5, further comprising the step of coating a first conductive metal layer on the portion of either molybdenum layer which is not in contact with the silicon die after the glass paste sintering step.

7. The method of claim 5, wherein after the glass paste sintering step, the rectifying device is placed in a mold prior to coating a resin onto the peripheral surface of the silicon die and the molybdenum layers for encapsulating the rectifying device, and further comprising the step of coating a second conductive metal layer on one surface of one molybdenum layer and the other surface of the other molybdenum layer which are not in contact with the silicon die respectively.

8. The method of claim 6 or 7, further comprising two conductive leads each welded to one of the first and the second conductive metal layers.
